(19) United States
(12) Patent Application Publication
(10) Pub. No.: US 2014/0326486 A1
(43) Pub. Date: Nov. 6, 2014

(54) PRINTED CIRCUIT BOARD

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventor: CHAO-RONG LAI, Shenzhen (CN)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 14/265,475

(22) Filed: Apr. 30, 2014

(30) Foreign Application Priority Data
May 2, 2013 (CN) 2013101577083

(51) Int. Cl. H05K 1/11; H05K 1/02

(52) U.S. Cl. CPC H05K 1/113; H05K 1/0206; H05K 2201/06; H05K 2201/095; H05K 2201/09481; H05K 2201/0137
USPC 174/252

(57) ABSTRACT

A printed circuit board (PCB) comprising a base board, the base board defines a thermal pad and a plurality of pin pads for solder an integrated circuit (IC) with a Quad Flat No-lead (QFN) package, wherein a plurality of thermal vias are defined on the thermal pad through the base board, a solder mask is defined around each of the thermal vias.

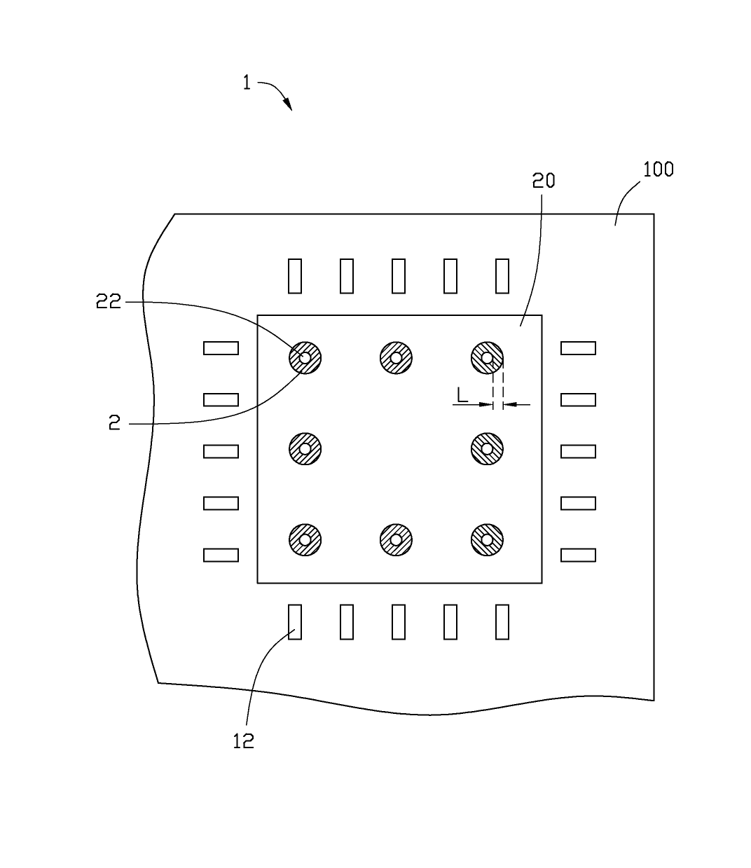

### FIELD

The present disclosure relates to a printed circuit board (PCB).

### BACKGROUND

An integrated circuit (IC) with a Quad Flat No-lead (QFN) package includes an exposed thermal pad to improve heat transfer from the IC (into the PCB). Heat transfer can be further facilitated by a thermal pad on the PCB and thermal vias through the PCB.

### BRIEF DESCRIPTION OF THE DRAWING

Many aspects of the embodiments can be better understood with reference to the following drawing. The components in the drawing are not necessarily drawn to scale, the emphasis instead being placed upon clearly illustrating the principles of the presented embodiments.

The figure is a diagram of an embodiment of a printed circuit board.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.” The reference “a plurality of” means “at least two.”

The figure shows that an embodiment of a PCB 1 of the present disclosure comprises a base board 100. The base board 100 defines a thermal pad 20 and a plurality of pin pads 12 for soldering an IC with QFN package. A plurality of thermal vias 22 is defined in the thermal pad 20 through the base board 100. An annular solder mask 2 is formed around each of the thermal vias 22. Concentric circles are formed by each of the thermal vias 22 and the solder mask 2 around the thermal via 22, and the radius difference of the concentric circles is L.

In at least one embodiment, material of the solder mark 2 is green oil. A shape of the solder mask 2 is not limited to annular. In other embodiment, the solder mask 2 can be other shapes formed around the thermal vias 22.

In at least one embodiment, the number of the thermal vias 22 is eight. Four thermal vias 22 are defined in four angles of the thermal pad 20 respectively, and a thermal via 22 is defined between every two adjacent thermal vias 22, to ensure heat transfer efficiency.

When the PCB 1 in reflow soldering, solder flow into the thermal pad 20 through a gap between the IC with QFN package and the base board 100, and be cut off by the solder marks 2 around the thermal vias 22. The solder marks 2 prevent the solder from flowing into the thermal vias 22 to avoid the PCB 1 from short-circuiting.

Even though numerous characteristics and advantages of the disclosure have been set forth in the foregoing description, together with details of the structure and function of the disclosure, the disclosure is illustrative only, and changes can be made in the details given, including matters of shape, size, and arrangement of parts within the principles of the disclosure to the full extent indicated by the broad general meaning of the terms in which the appended claims are expressed.

What is claimed is:

1. A printed circuit board (PCB) comprising a base board, the base board comprising a thermal pad and a plurality of pin pads for solder an integrated circuit (IC) with a Quad Flat No-lead (QFN) package, wherein a plurality of thermal vias are defined in the thermal pad through the base board, and a solder mask is defined around each of the thermal vias.

2. The PCB of claim 1, wherein each of the thermal vias and the solder mask around the thermal via form a concentric circle.

3. The PCB of claim 1, wherein the solder mark is made of green oil.
